(19) United States
(12) Patent Application Publication
(10) Pub. No.: US 2014/0261662 A1
(43) Pub. Date: Sep. 18, 2014

(54) METHOD OF MANUFACTURING A SOLAR CELL ELECTRODE

(71) Applicant: E I DU PONT DE NEMOURS AND COMPANY, Wilmington, DE (US)

(72) Inventor: NORIHIKO TAKEDA, KANAGAWA (JP)

(73) Assignee: E I DU PONT DE NEMOURS AND COMPANY, Wilmington, DE (US)

(21) Appl. No.: 14/197,334

(22) Filed: Mar. 5, 2014

Related U.S. Application Data
(60) Provisional application No. 61/802,791, filed on Mar. 18, 2013.

(51) Int. Cl. H01L 31/0224

(52) U.S. Cl. CPC H01L 31/022425
USPC 136/256; 438/98

(57) ABSTRACT

A method of manufacturing a p-type electrode of a solar cell comprising: (a) preparing an n-type semiconductor substrate comprising an n-type base layer, a p-type emitter and a passivation layer formed on the p-type emitter; (b) applying a conductive paste onto the passivation layer, wherein the conductive paste comprises, (i) 100 parts by weight of a conductive powder, (ii) 1 to 12 parts by weight of a lead-free glass frit comprising, 20 to 33 mol. % of Bi₂O₃, 25 to 40 mol. % of B₂O₃, 15 to 45 mol. % of ZnO, 0.5 to 9 mol. % of alkaline-earth metal oxide, alkali metal oxide or a mixture thereof, wherein the mot % is based on the total molar fraction of each component in the glass frit, and (iii) 5 to 40 parts by weight of an organic medium; and (c) firing the applied conductive paste.

### CROSS-REFERENCE TO RELATED APPLICATION

This application claims the benefit of U.S. Provisional Application No. 61/802,791, filed Mar. 18, 2013.

### FIELD OF THE INVENTION

The present invention is directed primarily to a solar cell, more specifically to a method of manufacturing a p-type electrode of a solar cell.

### TECHNICAL BACKGROUND OF THE INVENTION

Solar cell electrodes are required to have low electrical resistance to improve conversion efficiency (Eff) of solar cells, especially in the case of a p-type electrode that electrically contacts with a p-type emitter.

WO2010030652 discloses a method for producing a p-type electrode comprising the steps of: (1) applying a paste onto p-type emitter of the N-type base solar cell substrate, the paste comprises (a) electrically conductive particles containing silver particle and an added particle selected from the group consisting of Mo, Tc, Ru, Rh, Pd, W, Re, Os, Ir and Pt particles, (b) a glass frit and (c) a resin binder, and (2) firing the applied paste.

### SUMMARY OF THE INVENTION

An objective of the present invention is to provide a method of manufacturing a p-type electrode which has lower contact resistance to a p-type emitter.

An aspect of the invention relates to a method of manufacturing a p-type electrode of a solar cell comprising: (a) preparing a n-type semiconductor substrate comprising an n-type base layer, a p-type emitter and a passivation layer formed on the p-type emitter; (b) applying a conductive paste onto the passivation layer, wherein the conductive paste comprises, (i) 100 parts by weight of a conductive powder, (ii) 1 to 12 parts by weight of a lead-free glass frit comprising, 20 to 33 mole percent (mol. %) of bismuth oxide (Bi₂O₃), 25 to 40 mol. % of boron oxide (B₂O₃), 15 to 45 mol. % of zinc oxide (ZnO), 0.5 to 9 mol. % of alkaline-earth metal oxide, alkali metal oxide or a mixture thereof, wherein the mol. % is based on the total molar fraction of each component in the glass frit, and (iii) 5 to 40 parts by weight of an organic medium; and (c) firing the applied conductive paste.

Another aspect of the invention relates to a method of manufacturing a p-type electrode of a solar cell comprising: (a) preparing an n-type semiconductor substrate comprising an n-type base layer, a p-type emitter and a passivation layer formed on the p-type emitter; (b) applying a conductive paste onto the passivation layer, wherein the conductive paste comprises, (i) 100 parts by weight of a conductive powder, (ii) 1 to 12 parts by weight of a lead-free glass frit comprising, 36 to 55 mole percent (mot %) of bismuth oxide (Bi₂O₃), 29 to 52 mol. % of boron oxide (B₂O₃), 0 to 40 mol. % of zinc oxide (ZnO), 0.5 to 3 mol. % of silicon oxide (SiO₂), 0.5 to 3 mol. % of aluminum oxide (Al₂O₃), and 1 to 8 mol. % of alkaline-earth metal oxide, wherein the mol. % is based on the total molar fraction of each component in the glass frit, and (iii) 5 to 40 parts by weight of an organic medium; and (c) firing the applied conductive paste.

Another aspect of the invention relates to an n-type solar cell comprising the p-type electrode formed by the method above.

A p-type electrode and solar cell formed by the present invention obtains a superior electrical characteristic.

### BRIEF DESCRIPTION OF THE DRAWINGS

FIG. 1A to FIG. 1F are schematic diagrams illustrating a method of manufacturing a solar cell.

FIG. 2 is a schematic diagram illustrating a solar cell made in the Examples.

### DETAILED DESCRIPTION OF THE INVENTION

The method of manufacturing a p-type electrode is explained below.

The method of manufacturing the p-type electrode of a solar cell comprising: (a) preparing a n-type semiconductor substrate comprising an n-type base layer, a p-type emitter and a passivation layer formed on the p-type emitter; (b) applying a conductive paste onto the passivation layer; and (c) firing the applied conductive paste.

An embodiment of the manufacturing process of the p-type electrode is explained below along with FIG. 1A to FIG. 1F in the event of an N-type solar cell.

FIG. 1A shows an n-type semiconductor substrate 100 comprising an n-type base layer 10 and a p-type emitter 20 formed on one side of the n-type base layer 10.

The n-type base layer 10 can be defined as a semiconductor layer containing an impurity called donor dopant where the donor dopant introduces extra valence electrons in the semiconductor element. In the n-type base layer 10, free electrons are generated from the donor dopant in the conduction band.

The p-type emitter 20 can be defined as a semiconductor layer containing an impurity called acceptor dopant where the acceptor dopant introduces deficiency of valence electrons in the semiconductor element. In the p-type emitter, the acceptor dopant takes in free electrons from semiconductor element and consequently positively charged holes are generated in the valence band.

In the case of silicon semiconductor, the n-type base layer 10 can be formed by doping with phosphorus and the p-type emitter 20 can be formed by doping with boron. Alternatively, the p-type emitter 20 can be formed by ion implantation with a boron compound such as boron trifluoride (BF₃) as an ion source.

The thickness of the p-type emitter 20 can be, for example, 0.1 to 10% of thickness of the semiconductor substrate 100.

The n-type base layer 10 typically has a bulk resistivity of 1 to 10 ohm·cm and the p-type emitter 20 typically have has a sheet resistance on the order of several tens of ohms per square.

In FIG. 1B shows the n-type semiconductor substrate 100 further comprises a passivation layer 30 formed on the p-type emitter 20. The passivation layer works to reduce loss of charge carriers by recombination of electrons and positive holes at the surface of a substrate. The passivation layer 30 can also function as an anti-reflection coating (ARC) to reduce loss of incident light when the passivation layer 30 comes to the light receiving side.

Silicon nitride (SiNₓ), titanium oxide (TiO₂), aluminum oxide (Al₂O₃), silicon oxide (SiOₓ), silicon carbide (SiCₓ), amorphous silicon (a-Si), or indium tin oxide (ITO) can be used as a material for forming the passivation layer 30. Most commonly used is SiO₂, Al₂O₃, or SiNₓ.

Plasma-enhanced chemical vapor deposition (PECVD), atomic layer deposition (ALD), a thermal chemical vapor deposition (CVD) can be applicable to form the passivation layer 30.

The passivation layer may be multiple. The passivation layer may consist of two layers, for example two layers of Al₂O₃ and SiNₓ or two layers of SiO₂ and SiNₓ.

Thickness of the passivation layer 30 can be 20 to 400 nm. In FIG. 1C, a back surface field (BSF) 40 can be optionally formed on the opposite side of the p-type emitter of the substrate 100. For example, the BSF can be formed by further doping phosphorus (P). Phosphorus oxychloride (POCl₃) can be a dopant source. An ion implantation method using phosphine (PH₃) as an ion source can be also used.

In FIG. 1D, a passivation layer 50 is formed on the BSF layer 40. The passivation layer 50 can be also formed as described above for the passivation layer 30 on the p-type emitter 20. The thickness and composition of the passivation layer 50 can be same or different from the passivation layer 30.

In FIG. 1E, a conductive paste 70 is applied onto the passivation layer 50 on the side of the n-type base layer 10, and optionally dried. A commercially available conductive paste, for example PV159, PV16A, PV17F and PV18A from E.I. du Pont de Nemours and Company may be used for the conductive paste 70.

On the side of the p-type emitter 20, a conductive paste 60 is applied onto the passivation layer 30, and optionally dried. Composition of the conductive paste 60 is described in detail below.

The conductive paste 60 and 70 can be applied by screen printing in an embodiment.

The pattern of the applied conductive paste can comprise plural parallel lines called finger line or grid line and bus-bar vertically crossing to the finger lines in an embodiment, which is general and well known in the field of solar cell. The patterns on the front side and the back side of the cell can be either same or different.

Firing is then carried out in a furnace. The measured firing peak temperature on the surface of the substrate 100 is 450 to 1000° C. in an embodiment, 650 to 870° C. in another embodiment, and 700 to 800° C. in another embodiment. Firing total time may be from 20 seconds to 15 minutes. Within the ranges, less damage may occur to the semiconductor substrate 100. In another embodiment, the firing profile by the measured temperature can be 10 to 60 seconds at over 400° C. and 2 to 10 seconds at over 600° C.

As shown in FIG. 1F, the p-type electrode 61 is made by firing the conductive paste 60, and the n-type electrode 71 is made by firing the conductive paste 70. Both of the conductive paste 60 and 70 can be capable of firing through the passivation layer 30 and 50 respectively during firing to reach to the p-type emitter 20 and the BSF 40 respectively.

The N-type solar cell 80 comprises the n-type base layer 10, the p-type emitter 20 and the p-type electrode 61 to contact to the p-type emitter 20.

For a method of manufacturing of N-type solar cell 80 can be referred to the following references. They are herein incorporated by reference.
A. Weeber et al. Status of N-type Solar Cells for Low-Cost Industrial Production; Proceedings of 24th European Photovoltaic solar Energy Conference and Exhibition, 21-25 Sep. 2009, Hamburg, Germany
T. Buck et al. Industrial Screen Printed n-type Silicon Solar Cells with Front Boron Emitter and Efficiencies Exceeding 17%; Proceedings of 21st European Photovoltaic solar Energy Conference and Exhibition 4-9 Sep. 2006, Dresden, Germany
J. E. Cotter et al., P-Type versus n-Type Silicon Wafers: Prospects for High-Efficiency Commercial Silicon Solar Cells; IEEE transactions on electron devices; Vol. 53, No. 8, August 2006, pp 1893-1896.
L. J. Geerligs, et al., N-type solar grade silicon for efficient p⁺n solar cells: overview and main results of the EC NESSI project; European photovoltaic solar energy conference and exhibition 4-8 Sep. 2006.

Either the p-type emitter 20 or the n-type semiconductor substrate 10 can come to the light receiving side.

In another embodiment, the N-type solar cell 80 comprises the p-type electrode 61 and the p-type emitter 20 on the light receiving side.

In another embodiment, the N-type solar cell comprises the p-type electrode and the p-type emitter on the back side of the light receiving side (not shown).

In another embodiment, the N-type solar cell 80 can be a bifacial cell that receives light on both sides of the p-type emitter 20 and the n-type base layer 10. For manufacturing of bifacial cells, the following literature can be referred and can be herein incorporated by reference.
A. Kränzl et al. Bifacial Solar Cells on Multi-crystalline Silicon; Proceedings of 15th International Photovoltaic Science & Engineering Conference, Shanghai, China, 2005, pp. 885-886.

In another embodiment, the p-type electrode may be used in a back contact type solar cell that comprises the p-type emitter on the back side of the n-type semiconductor substrate. US20080230119 is herein incorporated by reference for the back contact type solar cell.

Next, the conductive paste 60 for the p-type electrode 61 is described below. The conductive paste includes at least a conductive powder, a lead-free glass frit and an organic medium.

### (i) Conducting Powder

The conductive powder is a metal powder having an electrical conductivity. The electrical conductivity of the conductive powder is 1.00×10⁷ Siemens (S)/m or higher at 293 Kelvin in an embodiment.

The conductive powder can comprise a metal selected from the group consisting of iron (Fe; 1.00×10⁷ S/m), aluminum (Al, 3.64×10⁷ S/m), nickel (Ni; 1.45×10⁷ S/m), copper (Cu; 5.81×10⁷ S/m), silver (Ag; 6.17×10⁷ S/m), gold (Au; 4.17×10⁷ S/m), molybdenum (Mo; 2.10×10⁷ S/m), tungsten (IN; 1.82×10¹ S/m), cobalt (Co; 1.46×10⁷ S/m), zinc (Zn; 1.64×10⁷ S/m), an alloy thereof and a mixture thereof in an embodiment.

The conductive powder can comprise a metal selected from the group consisting of Al, Cu, Ag, Zn, an alloy thereof and a mixture thereof in another embodiment. The conductive powder can comprise Al, Cu, Ag, Au, or an alloy thereof in another embodiment. In still another embodiment, the conductive powder can comprise an elemental Al powder, an elemental Ag powder or a mixture thereof. These metal powders have relatively high conductivity and easily found in the market.

Purity of the elemental metal powder such as the elemental Ag powder or the elemental Al powder can be 90 weight percent (wt %) or higher in an embodiment, 98 wt % or higher in another embodiment based on the weight of the elemental Ag powder and elemental Al powder respectively.

In an embodiment, the conductive powder comprises the elemental Ag powder and the elemental Al powder at the weight ratio (Ag:Al) of 97:3 to 99.5:0.5, and 97.5:2.5 to 99:1 in another embodiment.

The conductive powder can be an alloy powder comprises Ag, Al or both of Ag and Al, for example an alloy of Ag—Al, Ag—Cu, Ag—Ni, and Ag—Cu—Ni.

In an embodiment, the conductive powder can be flaky, spherical or nodular in shape. The nodular powder is irregular particles with knotted or rounded shapes.

The particle diameter (D50) of the conductive powder can be 0.1 to 10 μm in an embodiment, 1 to 7 μm in another embodiment, 2 to 4 μm in another embodiment. The conductive powder with the particle diameter can sinter properly during the firing step. The conductive powder can be a mixture of two or more of conductive powders with different particle diameters.

The particle diameter (D50) is obtained by measuring the distribution of the particle diameters by using a laser diffraction scattering method and can be defined as the diameter of particles at which 50% by weight of the particles are smaller. Microtrac model X-100 is an example of the commercially-available devices.

The conductive powder can be 60 to 90 weight percent (wt. %) in an embodiment, 69 to 87 wt. % in another embodiment, 78 to 84 wt. % in another embodiment based on the weight of the conductive paste. With such amount of the conductive powder in the conductive paste, the formed electrode can retain sufficient conductivity.

### (ii) Lead-Free Glass Frit

The lead-free glass frits melt and adhere to the semiconductor substrate to fix the electrode. The lead-free glass frit contains no lead compound such as lead oxide and lead fluoride as the starting materials. However, impurity level of lead which is not easily avoidable can be acceptable for the lead-free glass frit to contain. Specifically, lead is included in the lead free glass frit at less than 0.01 mole percent (mol. %) in an embodiment, at less than 0.001 mol. % in another embodiment based on the total molar fraction of each component in the glass frit, and no trace level in a further another embodiment.

Specimens of the general lead-free glass composition in molar percent are shown below, the Bi—B—Zn based glass compositions in Table 1 and the Bi—B—Si—Al based glass compositions in Table 2.

Unless especially stated, as used herein, mol. % is based on the total molar fraction of each component in the glass frit. The specimens are not limited to the lead-free glass frit composition; it can be contemplated that one of ordinary skill in the art of glass chemistry could make minor substitutions of additional ingredients and not substantially change the desired properties of the glass composition.

TABLE 1
(Bi—B—Zn based glass composition)

(mol. %)

| # | Bi₂O₃ | B₂O₃ | ZnO | BaO | CaO | Li₂O | MgO | Total |
|---|---|---|---|---|---|---|---|---|
| 1 | 28.4 | 36.0 | 35.6 | 0.0 | 0.0 | 0.0 | 0.0 | 100.0 |
| 2 | 50.0 | 50.0 | 0.0 | 0.0 | 0.0 | 0.0 | 0.0 | 100.0 |
| 3 | 50.0 | 10.0 | 40.0 | 0.0 | 0.0 | 0.0 | 0.0 | 100.0 |
| 4 | 10.0 | 50.0 | 40.0 | 0.0 | 0.0 | 0.0 | 0.0 | 100.0 |
| 5 | 36.6 | 36.7 | 26.7 | 0.0 | 0.0 | 0.0 | 0.0 | 100.0 |
| 6 | 63.4 | 23.3 | 13.3 | 0.0 | 0.0 | 0.0 | 0.0 | 100.0 |
| 7 | 23.3 | 63.4 | 13.3 | 0.0 | 0.0 | 0.0 | 0.0 | 100.0 |
| 8 | 23.3 | 23.3 | 53.4 | 0.0 | 0.0 | 0.0 | 0.0 | 100.0 |
| 9 | 43.4 | 43.3 | 13.3 | 0.0 | 0.0 | 0.0 | 0.0 | 100.0 |
| 10 | 23.3 | 43.4 | 33.3 | 0.0 | 0.0 | 0.0 | 0.0 | 100.0 |
| 11 | 43.4 | 23.3 | 33.3 | 0.0 | 0.0 | 0.0 | 0.0 | 100.0 |
| 12 | 27.8 | 35.3 | 34.9 | 2.0 | 0.0 | 0.0 | 0.0 | 100.0 |
| 13 | 9.6 | 48.0 | 38.4 | 4.0 | 0.0 | 0.0 | 0.0 | 100.0 |
| 14 | 22.4 | 60.8 | 12.8 | 4.0 | 0.0 | 0.0 | 0.0 | 100.0 |
| 15 | 22.4 | 22.4 | 51.2 | 4.0 | 0.0 | 0.0 | 0.0 | 100.0 |
| 16 | 27.3 | 34.5 | 34.2 | 4.0 | 0.0 | 0.0 | 0.0 | 100.0 |
| 17 | 35.2 | 35.2 | 25.6 | 4.0 | 0.0 | 0.0 | 0.0 | 100.0 |
| 18 | 48.0 | 48.0 | 0.0 | 4.0 | 0.0 | 0.0 | 0.0 | 100.0 |
| 19 | 48.0 | 9.6 | 38.4 | 4.0 | 0.0 | 0.0 | 0.0 | 100.0 |
| 20 | 60.8 | 22.4 | 12.8 | 4.0 | 0.0 | 0.0 | 0.0 | 100.0 |
| 21 | 41.6 | 41.6 | 12.8 | 4.0 | 0.0 | 0.0 | 0.0 | 100.0 |
| 22 | 22.4 | 41.6 | 32.0 | 4.0 | 0.0 | 0.0 | 0.0 | 100.0 |
| 23 | 41.6 | 22.4 | 32.0 | 4.0 | 0.0 | 0.0 | 0.0 | 100.0 |
| 24 | 26.7 | 33.8 | 33.5 | 6.0 | 0.0 | 0.0 | 0.0 | 100.0 |
| 25 | 25.6 | 32.4 | 32.0 | 10.0 | 0.0 | 0.0 | 0.0 | 100.0 |
| 26 | 27.8 | 35.3 | 34.9 | 0.0 | 2.0 | 0.0 | 0.0 | 100.0 |
| 27 | 27.3 | 34.6 | 34.2 | 0.0 | 4.0 | 0.0 | 0.0 | 100.0 |
| 28 | 26.7 | 33.8 | 33.5 | 0.0 | 6.0 | 0.0 | 0.0 | 100.0 |
| 29 | 28.1 | 35.6 | 35.2 | 0.0 | 0.0 | 1.0 | 0.0 | 100.0 |
| 30 | 27.8 | 35.3 | 34.9 | 0.0 | 0.0 | 2.0 | 0.0 | 100.0 |
| 31 | 27.3 | 34.6 | 34.2 | 0.0 | 0.0 | 4.0 | 0.0 | 100.0 |
| 32 | 27.3 | 34.6 | 34.2 | 0.0 | 0.0 | 0.0 | 4.0 | 100.0 |

However it was found that there was a certain range of Bi—B—Zn based glass compositions effecting superior electrical contact to a p-type electrode. The Bi—B—Zn based glass frit comprises 20 to 33 mol. % of bismuth oxide (Bi₂O₃), 25 to 40 mol. % of boron oxide (B₂O₃), 15 to 45 mol. % of zinc oxide (ZnO), 0.5 to 9 mol. % of alkaline-earth metal oxide, alkali metal oxide or a mixture thereof.

Bi₂O₃ is 23 to 30 mol. % in another embodiment, 25 to 27 mol. % in another embodiment.

B₂O₃ is 30 to 38 mol. % in another embodiment, 33 to 36 mol. % in another embodiment.

ZnO is 28 to 40 mol. % in another embodiment, 32 to 35 mol. % in another embodiment.

The alkaline-earth metal oxide, alkali metal oxide or a mixture thereof is 0.9 to 8 mol. % in another embodiment, 2.5 to 7.5 mol. % in another embodiment, 3 to 7.3 mol. % in another embodiment, and 5 to 7 mot % in still another embodiment.

The alkaline-earth metal oxide is a general term for the group consisting of beryllium oxide (BeO), magnesium oxide (MgO), calcium oxide (CaO), strontium oxide (SrO) and barium oxide (BaO). The alkaline-earth metal oxide can be BaO, CaO, MgO or a mixture thereof in another embodiment, BaO, CaO or a mixture thereof in another embodiment.

The alkaline metal oxide is a general term for the group consisting of lithium oxide (Li₂O), sodium oxide (Na₂O), potassium oxide (K₂O), rubidium oxide (Rb₂O) and cesium oxide (Cs₂O). The alkali metal oxide can be Li₂O in another embodiment.

The p-type electrode could electrically contact with the p-type emitter well by using such glass frit described above.

By using the Bi—B—Zn based glass frit comprising such amount of metal oxides, the p-type electrode could get superior electrical contact with the p-type emitter as shown in Example below.

Table 2 shows specimens of the Bi—B—Si—Al based glass composition.

TABLE 2
(Bi—B—Si—Al based glass composition)

(mol. %)

| # | Bi₂O₃ | B₂O₃ | SiO₂ | Al₂O₃ | ZnO | BaO | Total |
|---|---|---|---|---|---|---|---|
| 40 | 27 | 34 | 5 | 0 | 34 | 0 | 100 |
| 41 | 27 | 34 | 0 | 5 | 34 | 0 | 100 |
| 42 | 31.7 | 23.8 | 6.4 | 1.2 | 33.5 | 3.4 | 100 |
| 43 | 26.7 | 18.8 | 16.4 | 1.2 | 33.5 | 3.4 | 100 |
| 44 | 26.7 | 33.8 | 1.4 | 1.2 | 33.5 | 3.4 | 100 |
| 45 | 41.7 | 18.8 | 1.4 | 1.2 | 33.5 | 3.4 | 100 |
| 46 | 26.7 | 18.8 | 6.4 | 1.2 | 43.5 | 3.4 | 100 |
| 47 | 36.7 | 28.8 | 6.4 | 1.2 | 23.5 | 3.4 | 100 |
| 48 | 34.2 | 26.3 | 1.4 | 1.2 | 33.5 | 3.4 | 100 |
| 49 | 26.7 | 26.3 | 8.9 | 1.2 | 33.5 | 3.4 | 100 |
| 50 | 19.2 | 33.8 | 8.9 | 1.2 | 33.5 | 3.4 | 100 |
| 51 | 9.4 | 47.0 | 1.0 | 1.0 | 37.6 | 4.0 | 100 |
| 52 | 21.9 | 21.9 | 1.0 | 1.0 | 50.2 | 4.0 | 100 |
| 53 | 21.9 | 40.8 | 1.0 | 1.0 | 31.3 | 4.0 | 100 |
| 54 | 21.9 | 59.6 | 1.0 | 1.0 | 12.5 | 4.0 | 100 |
| 55 | 28.2 | 47.0 | 1.0 | 1.0 | 18.8 | 4.0 | 100 |
| 56 | 34.4 | 34.5 | 1.0 | 1.0 | 25.1 | 4.0 | 100 |
| 57 | 40.8 | 21.9 | 1.0 | 1.0 | 31.3 | 4.0 | 100 |
| 58 | 40.8 | 40.7 | 1.0 | 1.0 | 12.5 | 4.0 | 100 |
| 59 | 47.0 | 47.0 | 1.0 | 1.0 | 0.0 | 4.0 | 100 |
| 60 | 59.6 | 21.9 | 1.0 | 1.0 | 12.5 | 4.0 | 100 |

The Bi—B—Si—Al based glass compositions effecting superior electrical contact to a p-type electrode is also limited to a certain range. The Bi—B—Si—Al glass frit comprises 36 to 55 mol. % of bismuth oxide (Bi₂O₃), 29 to 52 mol. % of boron oxide (B₂O₃), 0.5 to 3 mol. % of silicon oxide (SiO₂), 0.5 to 3 mol. % of aluminum oxide (Al₂O₃), and 1 to 8 mol. % of alkaline-earth metal oxide.

B₂O₃ is 38 to 50 mol. % in another embodiment, 45 to 49 mol. % in another embodiment.

B₂O₃ is 35 to 50 mol. % in another embodiment, 42 to 49 mol. % in another embodiment.

SiO₂ is 0.7 to 1.5 mol. % in another embodiment.

Al₂O₃ is 0.7 to 1.5 mol. % in another embodiment.

ZnO is not essential. ZnO is at 40 mol. % at maximum in another embodiment, 20 mol. % at maximum in another embodiment. ZnO is zero in another embodiment.

The alkaline-earth metal oxide is 2 to 8 mol. % in another embodiment, 3 to 5 mol. % in another embodiment. The alkaline-earth metal oxide can be BaO in another embodiment.

The p-type electrode could electrically contact with the p-type emitter well by using such glass frit described above.

By using the Bi—B—Si—Al based glass frit comprising such amount of metal oxides, the p-type electrode could get superior electrical contact with the p-type emitter as shown in Example below.

Substitutions of glass former such as SiO₂, P₂O₅, GeO₂, V₂O₅ can be used either individually or in combination for Bi₂O₃ or B₂O₃ to achieve similar performance.

One or more intermediate oxides, such as Al₂O₃, TiO₂, Ta₂O₅, Nb₂O₅, ZrO₂ and SnO₂ can be substituted for other intermediate oxides such as ZnO to achieve similar performance.

The glass frit is 1 to 12 parts by weight when the conductive powder is 100 parts by weight, the glass frit is 3 to 10.5 parts by weight in another embodiment, and 7 to 9.5 parts by weight in another embodiment when the conductive powder is 100 parts by weight. The glass frit with such amount could function as binder in the electrode.

The glass frit compositions are described herein as including percentages of certain components. Specifically, the percentages of the components used as starting materials will be subsequently processed as described herein to form a glass frit. Such nomenclature is conventional to one of skill in the art.

In other words, the composition contains certain components, and the percentages of these components are expressed as a percentage of the corresponding oxide form. As recognized by one of skilled in glass chemistry, a certain portion of volatile species may be released during the process of making the glass. An example of a volatile species is oxygen.

If starting with a fired glass, one of skill in the art can estimate the percentages of starting components described herein (elemental constituency) using methods known to one of skill in the art including, but not limited to: Inductively Coupled Plasma-Emission Spectroscopy (ICPES), Inductively Coupled Plasma-Atomic Emission Spectroscopy (ICP-AES), and the like. In addition, the following exemplary techniques can be used: X-Ray Fluorescence spectroscopy (XRF); Nuclear Magnetic Resonance spectroscopy (NMR); Electron Paramagnetic Resonance spectroscopy (EPR); Mössbauer spectroscopy; Electron microprobe Energy Dispersive Spectroscopy (EDS); Electron microprobe Wavelength Dispersive Spectroscopy (WDS); Cathodoluminescence (CL).

The glass frit can have a softening point of 350 to 500° C. in an embodiment. The softening point can be determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. The glass softening point (Ts) is the temperature at the third inflection point in the DTA curve line.

The glass frits described herein can be manufactured by conventional glass making techniques. The following procedure is one example. Ingredients are weighed then mixed in the desired proportions and heated in a furnace to form a melt in platinum alloy crucibles. As well known in the art, heating is conducted to a peak temperature (800 to 1400° C.) and for a time such that the melt becomes entirely liquid and homogeneous. The molten glass is then quenched between counter rotating stainless steel rollers to form a 10-15 mil thick platelet of glass.

The resulting glass platelet is then milled to form a powder with its 50% volume distribution set between to a desired target (e.g. 0.8-3.0 μm). One skilled the art of producing glass frit may employ alternative synthesis techniques such as but not limited to water quenching, sol-gel, spray pyrolysis, or others appropriate for making powder forms of glass. US patent application numbers US 2006/231803 and US 2006/231800, which disclose a method of manufacturing a glass useful in the manufacture of the glass frits described herein, are hereby incorporated by reference herein in their entireties.

One of skill in the art would recognize that the choice of raw materials could unintentionally include impurities that may be incorporated into the glass during processing. For example, the impurities may be present in the range of hundreds to thousands ppm.

The presence of the impurities would not alter the properties of the glass, the conductive paste, or the electrode. For example, a solar cell containing the p-type electrode made with the conductive paste may have the electrical property herein, even if the paste includes impurities.

(iii) Organic Medium

The conductive paste contains an organic medium. The inorganic components such as the conductive powder and the glass frit is dispersed in the organic medium, for example, by mechanical mixing to form viscous compositions called “pastes”, having suitable consistency and rheology for printing.

There is no restriction on the composition of the organic medium. The organic medium can comprise at least an organic polymer and optionally a solvent in an embodiment.

A wide variety of inert viscous materials can be used as the organic polymer. The organic polymer can be epoxy resin, melamine resin, urea resin, unsaturated polyester resin, alkyd resin, polyurethane resin, an organic-inorganic hybrid resin, phenol resin, polyethylene, polypropylene, polyethylene terephthalate, polyamide, polyamide-imide, acrylic resin, phenoxy resin, ethyl cellulose or a mixture thereof.

The solvent can be optionally added to the organic medium to adjust the viscosity of the conductive paste if necessary. In an embodiment, the solvent can comprise texanol, ester alcohol, terpineol, kerosene, dibutylphthalate, butylcarbitol, butylcarbitol acetate, hexylene glycol or a mixture thereof.

The organic medium is 5 to 40 parts by weight, 10 to 30 parts by weight in another embodiment when the conductive powder is 100 parts by weight.

### (iv) Additive

Thickener, stabilizer, or surfactant as additives may be added to the conductive paste of the present invention. Other common additives such as a dispersant, viscosity-adjusting agent, and so on can also be added. The amount of the additive depends on the desired characteristics of the resulting electrically conducting paste and can be chosen by people in the industry. The additives can also be added in multiple types.

### Examples

The present invention is illustrated by, but is not limited to, the following example.

### Conductive Paste Preparation

The conductive paste was prepared with the following material and procedure.

Conductive powder: 100 parts by weight of a mixture of an elemental Ag powder and an elemental Al powder at the weight ratio of 98.2:1.8 was used. The particle diameter (D50) of the Ag powder and the Al powder was 3.0 μm and 3.5 μm respectively.

Glass frit: 8.7 parts by weight of the Bi—B—Zn based glass frit was used. The compositions of the Bi—B—Zn based glass frit were shown in Table 3 selected out of Table 1. The particle diameter (D50) of the glass frit was 2.0 μm.

Organic medium: 13.1 parts by weight of a texanol solution of ethyl cellulose was used.

Additive: 0.4 parts by weight of a viscosity-adjusting agent was used.

A mixture of the organic medium and the additive was mixed for 15 minutes. To enable the uniform dispersion of a small amount of Al powder in the conductive paste, the Ag powder and the Al powder were dispersed in the organic medium separately to mix together afterward.

The Al powder was separately added to the some organic medium and mixed for 15 minutes to prepare an Al slurry.

The glass frit was dispersed in the rest of the organic medium and mixed for 15 minutes and then the Ag powder was incrementally added to prepare an Ag paste. The Ag paste was separately passed through a 3-roll mill at progressively increasing pressures from 0 to 400 psi. The gap of the rolls was adjusted to 1 mil.

Then the Ag paste and the Al slurry were mixed together to prepare the conductive paste.

The conductive paste viscosity was adjusted by adding the organic medium to 260 Pa·s as measured with a viscometer Brookfield HBT using a spindle #14 at 10 rpm at room temperature. The degree of dispersion as measured by fineness of grind was 18/8 or less.

### Forming Solar Cell Electrode

An n-type semiconductor substrate of size of 30 mm×30 mm square that had an n-type base layer, a p-type emitter and a passivation layer was prepared as illustrated in FIG. 1B. The n-type semiconductor substrate was a phosphorus-doped silicon wafer. The p-type emitter was formed by doping with boron. The passivation layer was a double layer of a SiO₂ layer and a SiN_{X} layer and 90 nm thick.

On the other side of the p-type emitter, the surface of the n-type base layer was doped with additional phosphorus to form BSF. The SiN_{X} passivation layer of 70 nm thickness was formed over the BSF as illustrated in FIG. 1D.

The conductive paste formed above was screen printed onto the SiO₂/SiNₓ passivation layer on the p-type emitter. The printed pattern was fourteen parallel finger lines 201 with 70 μm wide, 27 mm long, 15 μm thick in average and a bus bar 202 as shown in FIG. 2. Intervals of the finger lines were about 2.1 mm. The printed conductive paste was dried at 150° C. for 5 minutes in a convection oven.

The dried conductive paste was fired with the p-type emitter facing upward in the furnace (CF-7210B, Despatch Industries) for 80 seconds at the measured peak temperature of 754° C. The furnace setting peak temperature was 885° C. The firing profile by measured temperature was over 400° C. for 22 seconds and over 600° C. for 6 seconds. The firing profile was measured with a K-type thermocouple attaching to the upper surface of the substrate and an environmental data logger (Datapaq® Furnace Tracker® System, Model DP9064A, Datapaq Ltd.). The belt speed of the furnace was set to 550 cpm.

### Measurement

To measure specific contact resistance (sR_{c}) of the p-type electrode formed above, the both edges of the solar cell were cut off by laser scribing at the dot-lines 203 as illustrated in FIG. 2. The solar cell after laser scribing was 30 mm×20 mm square and the finger lines were 20 mm long.

The sR_{c} between the finger line and the p-type emitter was measured by using a source meter (Keithley instruments model 2400). A transfer length method (TLM) based technique was used to get one value of R_{c} from neighboring four finger lines as follows. TLM method can be referred to the literature, “Semiconductor Material and Device Characterization” 3rd Ed. D. K. Schroder, Wiley-Interscience, New Jersey, 2006.

The set of measurements consisted of the following two steps: (1) measuring voltage between inner two lines 211 arbitrarily selected while flowing a direct current of 10 mA through them, which gives a sum of 2×R_{c} and Rₛₕₑₑₜ where R_{c} was average contact resistance of the inner two lines and Rₛₕₑₑₜ was sheet resistance of the p-type emitter; (2) measuring voltage between the inner two lines 211 while flowing a direct current between outer two lines 212 next to the inner lines 211, which gave Rₛₕₑₑₜ.

R_{c} was the half value of the resulting data in step (1) from which the resulting data in step (2) was taken away, calculated as R_{c}=[(2×R_{c}+Rₛₕₑₑₜ)−Rₛₕₑₑₜ]/2. The average of Rₛₕₑₑₜ was about 60 ohm/square.

sR_{c} was calculated as sR_{c}=R_{c}×W×L where d represents line width and W represents line length.

### Result

sR_{c} of the p-type electrode to the p-type emitter was shown in Table 3. The all p-type electrodes showed sR_{c} of 7.0 mohm·cm² or lower except for using glass frit #1 and 25.

TABLE 3
(Bi—B—Zn based glass composition)

(mol. %)

| | | | | | | | | Ts | |
|---|---|---|---|---|---|---|---|---|---|
| # | Bi₂O₃ | B₂O₃ | ZnO | BaO | CaO | Li₂O | MgO | (° C.) | sRc* |
| 1 | 28.4 | 36 | 35.6 | 0 | 0 | 0 | 0 | 467 | 7.2 |
| 12 | 27.8 | 35.3 | 34.9 | 2.0 | 0 | 0 | 0 | 459 | 5.6 |
| 16 | 27.3 | 34.5 | 34.2 | 4.0 | 0 | 0 | 0 | 462 | 6.3 |
| 24 | 26.7 | 33.8 | 33.5 | 6.0 | 0 | 0 | 0 | 459 | 5.3 |
| 25 | 25.6 | 32.4 | 32 | 10.0 | 0 | 0 | 0 | 457 | 10.4 |
| 26 | 27.8 | 35.3 | 34.9 | 0 | 2.0 | 0 | 0 | 452 | 5.5 |
| 27 | 27.3 | 34.6 | 34.2 | 0 | 4.0 | 0 | 0 | 466 | 6.0 |
| 28 | 26.7 | 33.8 | 33.5 | 0 | 6.0 | 0 | 0 | 467 | 5.3 |
| 29 | 28.1 | 35.6 | 35.2 | 0 | 0 | 1.0 | 0 | 457 | 6.5 |
| 30 | 27.8 | 35.3 | 34.9 | 0 | 0 | 2.0 | 0 | 459 | 6.7 |
| 31 | 27.3 | 34.6 | 34.2 | 0 | 0 | 4.0 | 0 | 446 | 5.5 |
| 32 | 27.3 | 34.6 | 34.2 | 0 | 0 | 0 | 4.0 | 467 | 7.0 |

*Unit of sR_{c} is mohm · cm².

Next, the Bi—B—Si—Al based glass composition in Table 2 was examined. The solar cell was made and the sR_{c} was measured in same manner as described above except for replacing the Bi—B—Zn based glass with the Bi—B—Si—Al based glass frit and the firing temperature. The measured peak temperature was 714° C. while the furnace's setting peak temperature was 825° C.

The measured sR_{c} converted to relative values with calculating formula (1).

Relative sR_{c} at glass #X=100/(sR_{c} at glass #40)×sR_{c} at glass #X (1)

The p-type electrodes using the Bi—B—Si—Al based glass frit at #58 and #59 showed drastically low relative sR_{c} lower than 70 while all the other electrodes had high relative sR_{c} as shown in Table 4.

TABLE 4
(Bi—B—Si—Al based glass composition)

(mol. %)

| | | | | | | | | Relative |
|---|---|---|---|---|---|---|---|---|
| # | Bi₂O₃ | B₂O₃ | SiO₂ | Al₂O₃ | ZnO | BaO | Ts (° C.) | sRc |
| 40 | 27.0 | 34.0 | 5.0 | 0.0 | 34.0 | 0.0 | 473 | 100 |
| 41 | 27.0 | 34.0 | 0.0 | 5.0 | 34.0 | 0.0 | 479 | 131 |
| 42 | 31.7 | 23.8 | 6.4 | 1.2 | 33.5 | 3.4 | 452 | 150 |
| 43 | 26.7 | 18.8 | 16.4 | 1.2 | 33.5 | 3.4 | 483 | 159 |
| 44 | 26.7 | 33.8 | 1.4 | 1.2 | 33.5 | 3.4 | 471 | 74 |
| 45 | 41.7 | 18.8 | 1.4 | 1.2 | 33.5 | 3.4 | 416 | 402 |
| 46 | 26.7 | 18.8 | 6.4 | 1.2 | 43.5 | 3.4 | 463 | 366 |
| 47 | 36.7 | 28.8 | 6.4 | 1.2 | 23.5 | 3.4 | 438 | 102 |
| 48 | 34.2 | 26.3 | 1.4 | 1.2 | 33.5 | 3.4 | 433 | 189 |
| 49 | 26.7 | 26.3 | 8.9 | 1.2 | 33.5 | 3.4 | 464 | 93 |
| 50 | 19.2 | 33.8 | 8.9 | 1.2 | 33.5 | 3.4 | 503 | 501 |
| 51 | 9.4 | 47.0 | 1.0 | 1.0 | 37.6 | 4.0 | 560 | 2023 |
| 52 | 21.9 | 21.9 | 1.0 | 1.0 | 50.2 | 4.0 | 474 | 160 |
| 53 | 21.9 | 40.8 | 1.0 | 1.0 | 31.3 | 4.0 | 499 | 266 |
| 54 | 21.9 | 59.6 | 1.0 | 1.0 | 12.5 | 4.0 | 552 | 1055 |
| 55 | 28.2 | 47.0 | 1.0 | 1.0 | 18.8 | 4.0 | 455 | 228 |
| 56 | 34.4 | 34.5 | 1.0 | 1.0 | 25.1 | 4.0 | 449 | 139 |
| 57 | 40.8 | 21.9 | 1.0 | 1.0 | 31.3 | 4.0 | ND | 453 |
| 58 | 40.8 | 40.7 | 1.0 | 1.0 | 12.5 | 4.0 | 441 | 69 |
| 59 | 47.0 | 47.0 | 1.0 | 1.0 | 0.0 | 4.0 | 438 | 60 |
| 60 | 59.6 | 21.9 | 1.0 | 1.0 | 12.5 | 4.0 | ND | 573 |

*ND: Not determined since the third flection point was not clearly identified in the DTA curve for #57 and #60.

What is claimed is:

1. A method of manufacturing a p-type electrode of a solar cell comprising:
(a) preparing an n-type semiconductor substrate comprising an n-type base layer, a p-type emitter and a passivation layer formed on the p-type emitter;
(b) applying a conductive paste onto the passivation layer, wherein the conductive paste comprises,
(i) 100 parts by weight of a conductive powder,
(ii) 1 to 12 parts by weight of a lead-free glass frit comprising, 20 to 33 mole percent (mol. %) of bismuth oxide (Bi₂O₃), 25 to 40 mol. % of boron oxide (B₂O₃), 15 to 45 mol. % of zinc oxide (ZnO), 0.5 to 9 mol. % of alkaline-earth metal oxide, alkali metal oxide or a mixture thereof, wherein the mot % is based on the total molar fraction of each component in the glass frit, and
(iii) 5 to 40 parts by weight of an organic medium; and
(c) firing the applied conductive paste.

2. The method of claim 1, wherein the softening point of the lead-free glass frit is 350 to 500° C.

3. The method of claim 1, wherein the alkaline-earth metal oxide is barium oxide (BaO), calcium oxide (CaO), magnesium oxide (MgO) or a mixture thereof and the alkali metal oxide is lithium oxide (Li₂O).

4. The method of claim 1, wherein the measured firing temperature in the firing step is 450 to 1000° C.

5. The method of claim 1, wherein the conductive powder comprises an elemental Ag powder and an elemental Al powder at the weight ratio of 97:3 to 99.5:0.5.

6. An N-type solar cell comprising the p-type electrode formed by the method of claim 1.

7. A method of manufacturing a p-type electrode of a solar cell comprising:
(a) preparing an n-type semiconductor substrate comprising an n-type base layer, a p-type emitter and a passivation layer formed on the p-type emitter;
(b) applying a conductive paste onto the passivation layer, wherein the conductive paste comprises,
(i) 100 parts by weight of a conductive powder,
(ii) 1 to 12 parts by weight of a lead-free glass frit comprising, 36 to 55 mole percent (mol. %) of bismuth oxide (Bi₂O₃), 29 to 52 mol. % of boron oxide (B₇O₃), 0.5 to 3 mol. % of silicon oxide (SiO₂), 0.5 to 3 mol. % of aluminum oxide (Al₂O₃), and 1 to 8 mol. % of alkaline-earth metal oxide, wherein the mol. % is based on the total molar fraction of each component in the glass frit, and
(iii) 5 to 40 parts by weight of an organic medium; and
(c) firing the applied conductive paste.

8. The method of claim 7, wherein softening point of the lead-free glass frit is 350 to 500° C.

9. The method of claim 7, wherein the alkaline-earth metal oxide is barium oxide (BaO).

10. The method of claim 7, wherein measured firing temperature in the firing step is 450 to 1000° C.

11. The method of claim 7, wherein the conductive powder comprises an elemental Ag powder and an elemental Al powder at the weight ratio of 97:3 to 99.5:0.5.

12. An n-type solar cell comprising the p-type electrode formed by the method of claim 7.
